(19) United States
(12) Patent Application Publication
(10) Pub. No.: US 2018/0123567 A1
(43) Pub. Date: May 3, 2018

(54) LINEARIZED NEGATIVE IMPEDANCE CONVERTER MATCHING CIRCUITS AND IMPEDANCE ADJUSTMENT CIRCUIT FOR A NEGATIVE IMPEDANCE CONVERTER

(71) Applicant: Smart Antenna Technologies Ltd., Birmingham (GB)

(72) Inventors: Sampson Hu, Birmingham (GB); Liang Wan, Birmingham (GB)

(21) Appl. No.: 15/560,899

(22) PCT Filed: Mar. 24, 2016
(86) PCT No.: PCT/GB2016/050859

§ 371 Date: Sep. 22, 2017

(30) Foreign Application Priority Data
Mar. 25, 2015 (GB) 1505062.8
Mar. 25, 2015 (GB) 1505063.6

(51) Int. Cl. H03H 11/30; H03H 11/44

(52) U.S. Cl. CPC H03H 11/30; H03H 11/44

(57) ABSTRACT

There is disclosed a negative impedance converter for a matching circuit for matching an impedance of an antenna to an impedance of an RF source or load. The negative impedance converter comprises first and second transistors connected in a cross-over configuration. Each transistor has a source or emitter, a drain or collector and a gate or base, and each transistor further has a first biasing circuit connected to its gate or base. The first biasing circuit comprises a first DC biasing signal source and a first diode or a third transistor connected between the first DC biasing signal source and the gate or base. There is also disclosed a negative impedance converter for a matching circuit for matching an impedance of an antenna to an impedance of an RF source or load. The negative impedance converter comprises first and second transistors connected in a cross-over configuration, each transistor having a source or emitter, a drain or collector and a gate or base. The source or emitter of one transistor is configured as an RF input port and the source or emitter of the other transistor is configured as an RF output port. The drain or collector of the first transistor is connected to the gate or base of the second transistor and the drain or collector of the second transistor is connected to the gate or base of the first transistor. An impedance is connected between the drain or collector of the first transistor and the drain or collector of the second transistor. The negative impedance converter is further provided with a passive impedance adjustment network connected between the source or emitter of the first transistor and the source or emitter of the second transistor.

This invention relates to matching circuits to match antennas to RF sources and, in particular, to matching circuits comprising a negative impedance converter provided with bias circuitry configured to improve linearity performance. In other aspects, this invention relates to matching circuits to match antennas to RF sources and, in particular, to an impedance adjustment circuit for a negative impedance converter implemented in a matching circuit.

### BACKGROUND

Electrically small antennas can be generally classified as TM (transverse magnetic) and TE (transverse electric) mode antennas. For a TM mode small antenna, which is widely used in wireless communication systems, the input impedance is considerably reactive with a small real part. It is therefore critical to match the antenna to the receiver or transmitter to maximise the total efficiency in the frequency range of interest.

Normally, an electrically small TM mode antenna can be characterised by or represented as a series connected combination of a resistor, a capacitor and an inductor. FIGS. 1 and 2 show that, at low frequencies, the reactance can equally be represented by a series connected capacitor and inductor, with the capacitor playing a dominant role in the reactance. The resistor represents the resistance of the radiating element of the antenna.

There are two different ways to match a highly reactive antenna of this type. One approach is conventional passive matching, where a large series inductor Lₑₓₜ is placed between the antenna and the signal port as a necessary component. However, the resistive loss that is introduced by the inductor Lₑₓₜ dramatically degrades the total efficiency. In fact, even with lossless inductors, the match is effective over only extremely small instant bandwidths because the reactive part of the electrically small antenna cannot be neutralised over a broad frequency band with passive components (the real part of the impedance is much smaller than the imaginary part). This is illustrated in FIG. 3.

The other approach uses an NIC (negative impedance converter) to create a negative capacitor, which can then be configured to cancel the reactance of the antenna as much as possible. This is a type of non-Foster impedance matching, and is illustrated in FIG. 4.

There is a relationship between antenna size and the realisable bandwidth as defined by the Chu limit (Chu, L. J.; “Physical limitations of omni-directional antennas”; Journal Applied Physics 19: 1163-1175; December 1948). The Chu limit gives the relationship between the radius of the circle that completely circumscribes an antenna and the Q of the antenna. However, McLean (McLean, J. S.; “A re-examination of the fundamental limits on the radiation Q of electrically small antennas”; IEEE Transactions on Antennas and Propagations; Vol. 44; No. 5; pp. 672-676; May 1996) redefined how the Q of an antenna should be calculated, and this is given in equation 1.1:

$$Q = \begin{matrix}1 \\ ( {k}^{3} {a}^{3} )\end{matrix} \vert \begin{matrix}1 \\ ( ka )\end{matrix} \qquad ( 1.1 )$$

where k is the wave number and a is the radius of a sphere that completely circumscribes the antenna as shown in FIG. 5.

McLean's equation is a derivation from the original Chu limits equations. There has also been much research into ways of improving the gain of an antenna through the use of matching networks, but this is also bounded by the Harrington limits (Harrington, R. F.; “Effect of antenna size on gain, bandwidth and efficiency”; Journal of Research of the National Bureau of Standards—D. Radio Propagation; vol. 64D; p. 12; 29 Jun. 1959) on antennas as given in:

G=(ka)²+2ka (1.2)

The Chu limit can be related to the antenna bandwidth by rewriting the Q of the antenna as shown in equation 1.3:

$$Q = \begin{matrix}{f}_{c} \\ Δ f\end{matrix} = \begin{matrix}1 \\ ( {k}^{3} {a}^{3} )\end{matrix} \vert \begin{matrix}1 \\ ( ka )\end{matrix} \qquad ( 1.3 )$$

where f_{c} is the antenna centre frequency at resonance and Δf is the bandwidth of the antenna.

Comparing equation 1.1 with equation 1.3, it can be seen that reducing the radius of the sphere which translates to a physical reduction in the antenna size, the antenna bandwidth also reduces. The reduction in size means that the antenna radiation resistance also reduces, and this in turn leads to a reduction the antenna efficiency. From equation 1.2, it is clear that antenna gain is also proportional to the antenna size a.

These two fundamental limits on the antenna make it difficult to provide a small antenna with a low Q (wideband). However, more and more devices these days require smaller antennas and there is need for these antennas to still have wide usable bandwidths.

Passive matching networks help to match antennas, but because they involve resonating the reactive part of the antenna with passive elements, they only give a good match at specific frequencies. Away from the specific frequency, the antenna return loss decreases. This necessitates the use of multiple or reconfigurable matching networks to cover wide frequency bands. However, using non-Foster elements could help provide continuous wideband matching because unlike Foster elements, the slope of the reactance versus frequency of a non-Foster element is always negative as shown in FIG. 4.

With these properties, non-Foster elements are able to cancel out completely the reactance of other elements and antennas because of the difference in slope and direction of rotation on the Smith chart.

One implementation of non-Foster elements is through the use of NICs (negative impedance converters). NICs were first proposed by Linvill (Linvill, J. G.; “Transistor negative-impedance converters”; Proc. IRE; vol 41, pp 725-729; 1953). The Linvill NIC consists of two transistors connected in a common base configuration. “Common base” or “common gate” refers to a specific input and output setup of a transistor in amplifier applications. In a Linvill type NIC, the RF input terminal is connected to the emitter or source of one transistor, and the RF output terminal to the emitter or source of the other transistor (in fact, since an NIC is normally a bidirectional device, it does not matter which terminal is used as the RF input and which as the RF output). The reactance to be inverted is connected between the two collectors or drains, and the base or gate of each transistor is connected to the collector or drain of the other transistor in the form of a feedback path. The emitters or sources form the two ports of the NIC. The circuit schematic of the NIC is shown in FIG. 6.

NICs offer useful features when used for matching antennas to transceiver RF modules. As NICs are active matching circuits, they will consume power, and the amount of power consumed will depend on the maximum power to be transmitted. A more conventional design of NIC is usually based on satisfying the maximum transmitter power bias condition and then using the NIC with the same bias for lower transmitter powers. This will work, but the amount of battery power consumed at lower transmit powers in a handset, tablet or other mobile device is wasteful. A conventional NIC setup is shown in FIG. 7. The NIC is located between the antenna and the RF module (Tx/Rx).

The parameters that are optimised for NIC are:

a) Compression point (P_{1dB})

b) Third order intercept point/IMD3

c) Noise figure

d) Antenna efficiency

e) Antenna matched bandwidth

f) Antenna return loss/VSWR

For the maximum transmitter power case, a high bias current is required to meet the linearity requirement for 3GPP/4G LTE applications—a typical NIC bias current from a 3V battery could be as high as 484 mA. This may satisfy the linearity requirement at maximum transmitter power (24 dBm for LTE), but for lower transmit powers this is clearly wasteful.

It is known from U.S. Pat. No. 7,852,174 to provide a negative capacity circuit for high frequencies applications. It is also known from US2006/0261902 to provide a voltage-controlled oscillator for a wireless transceiver including a differential negative impedance circuit. However, in both of these NIC devices, bias is applied to both the base of one transistor and to the collector of the other transistor.

The circuit schematic of another conventional Linvill-type NIC is shown in FIG. 8. The NIC comprises first and second biased transistors 51, 52 connected in a crossover configuration. It will be understood that the NIC may comprise field effect transistors, in which case the transistors 51, 52 will have a source 55, 55′, a drain 54, 54′ and a gate 53, 53′. Alternatively, the NIC may comprise bipolar junction transistors, in which case the transistors 51, 52 will have an emitter 55, 55′, a collector 54, 54′ and a base 53, 53′.

The collector or drain 54 of the first transistor 51 is connected to the base or gate 53′ of the second transistor 52, and the collector or drain 54′ of the second transistor 52 is connected to the base or gate 53 of the first transistor 51. A predetermined impedance is provided between the respective collectors or drains 54, 54′ on the one hand, and the respective bases or gates 53, 53′ on the other hand, of the first and second transistors 51, 52. The predetermined impedance determines the negative impedance that the NIC applies to an RF signal passing between the input port 100 and the output port 101. The predetermined impedance may consist of a resistor 56, an inductor 57 and a capacitor 58 connected in series between the respective collectors or drains 54, 54′.

FIG. 9 shows how the Linvill-type NIC of FIG. 8 can be implemented as a non-Foster matching circuit for an electrically small antenna 59. An external inductor 60 is connected between the antenna 59 and the source or emitter 55′ of the second transistor 52 (the RF input of the NIC). The negative impedance generated by the NIC is used to neutralise the reactance of the external inductor 60 and the antenna 59. An external capacitor 61 is connected to the source or emitter 55 of the first transistor 51 so as to transform the neutralised impedance to 50Ω at the RF output port of the NIC.

However, the present Applicant has found that conventional Linvill-type NIC matching circuits as shown in FIG. 9 are not always ideal enough to generate the precise negative impedance that is required in particular antenna applications. This can result in lower total efficiency, higher noise figures and potential instability.

It is known from WO2013/006732 and WO2013/006740 to provide non-Foster circuits (i.e. NICs), but there is no consideration given to the specific problems caused by additional instability that might be introduced by incorporating a combination of negative resistance, negative inductance and negative capacitance.

### BRIEF SUMMARY OF THE DISCLOSURE

Viewed from a first aspect, there is provided a negative impedance converter for a matching circuit for matching an impedance of an antenna to an impedance of an RF source or load, the negative impedance converter comprising first and second transistors connected in a cross-over configuration, each transistor having a source or emitter, a drain or collector and a gate or base, and each transistor further having a first biasing circuit connected only to its gate or base and not to the drain or collector of the other transistor, wherein the first biasing circuit comprises a first DC biasing signal source and a first diode connected between the first DC biasing signal source and the gate or base.

Viewed from a second aspect, there is provided a negative impedance converter for a matching circuit for matching an impedance of an antenna to an impedance of an RF source or load, the negative impedance converter comprising first and second transistors connected in a cross-over configuration, each transistor having a source or emitter, a drain or collector and a gate or base, and each transistor further having a first biasing circuit connected only to its gate or base and not to the drain or collector of the other transistor, wherein the first biasing circuit comprises a first DC biasing signal source and a third transistor connected between the first DC biasing signal source and the gate or base.

The first diode or third transistor helps to promote RF linearization.

Additionally, there may be provided a second diode connected in series with the first diode or the third transistor, or a further transistor connected in series with the first diode or the third transistor.

The second diode or further transistor helps to compensate for voltage changes in the first diode or third transistor due to physical environmental changes, such as temperature.

It will be understood that the NIC may comprise field effect transistors, in which case the transistors will have a source, a drain and a gate. Alternatively, the NIC may comprise bipolar junction transistors, in which case the transistors will have an emitter, a collector and a base.

The NIC has an RF input port connected to the source or emitter of the first transistor, and an RF output port connected to the source or emitter of the second transistor. The collector or drain of the first transistor is connected to the base or gate of the second transistor, and the collector or drain of the second transistor is connected to the base or gate of the first transistor. A predetermined impedance is provided between the respective collectors or drains on the one hand, and the respective bases or gates on the other hand, of the first and second transistors. The predetermined impedance determines the negative impedance that the NIC applies to an RF signal passing between the input port and the output port. The predetermined impedance is preferably adjustable, for example by employing a variable capacitor and/or a variable inductor. The predetermined impedance may be adjustable by way of a control input from a digital controller, such as a microprocessor, field programmable gate array, PIC or the like.

The base or gate is provided with a conductive base or gate connection to allow an RF signal to be connected to the base or gate. The base or gate connection is connected to the first biasing circuit between the respective first and second diodes, third and fourth transistors, or first diode and third transistor. The first biasing circuit applies a first biasing signal to the base or gate, with the RF signal being superposed on the first biasing signal. Where the transistors are bipolar junction transistors, the first biasing signal will be a biasing current. Where the transistors are field effect transistors, the first biasing signal will be a biasing voltage.

The first biasing circuit further comprises a source of biasing signal, such as a DC source, and may further include one or more resistors, capacitors and/or inductors so as to allow the first biasing signal to be conditioned as required.

The diodes or transistors or diode and transistor are connected in series with each other with the same polarity, and are connected between the source of biasing signal and ground. Resistors may be provided in the first biasing circuit to act as a potential divider, thereby allowing the first biasing circuit to apply the required first biasing signal to the base or gate. The diodes or transistors are also configured to help apply the desired bias. A capacitor may be connected in parallel with one of the diodes or transistors, advantageously the diode or transistor closest to the source of biasing signal, and an additional capacitor may be connected between the input of this diode or transistor and ground, so as to enable RF power linearization. In other words, the additional capacitor connected between the input of the diode or transistor and ground enables a DC operation current to increase adaptively with an increase in the power level of the input signal.

When the functional transistors of the NIC are field effect transistors (FETs), the first and second diodes (or third transistor and further transistor, or first diode and further transistor), in combination with resistors in the first biasing circuit, are used to provide a DC biasing voltage to the gate of the functional FET of the NIC. This gate biasing voltage controls the biasing current from the drain to the source of the functional FET of the NIC. When the functional transistors of the NIC are bipolar junction transistors (BJTs), the first and second diodes (or third transistor and further transistor, or first diode and further transistor), in combination with resistors in the first biasing circuit, are used to provide a DC biasing current to the base of the functional BJT of the NIC. This gate biasing current controls the biasing current from the collector to the emitter of the functional BJT of the NIC. The function of the second diode (or the further transistor) is to compensate the DC voltage or current change on the first diode (or the third transistor) that may arise due to changes in physical conditions (for example an external or internal temperature change). The first diode (or the third transistor), together with a parallel capacitor and a grounded capacitor, serves to provide NIC RF linearization. When the input RF signal power is injected at the source or emitter terminal of the NIC functional transistor, part of the signal is coupled to the gate or base terminal of the NIC functional transistor, and some of this part is coupled to ground by the grounded capacitor. Meanwhile, the first diode (or the third transistor) rectifies the coupled RF signal to decrease its equivalent resistance. As a result, the DC voltage at the gate of the NIC functional transistor (or the DC current at the base of the NIC functional transistor) is increased and the biasing current from drain to source (or from collector to emitter) of the NIC functional transistor is increased, which improves the linearity of the NIC. The grounded and parallel capacitors can be used to control the strength of RF signal coupling and rectification, and an inductor between the two diodes (or two transistors, or one diode and one transistor) can be used to choke the RF signal and further to improve RF power linearization.

The first biasing circuit helps to improve the efficiency and hence power handling capability of the negative impedance converter. In particular, third order intermodulation distortion, IMD3, is much reduced at higher input powers.

A second biasing circuit, comprising a second DC biasing source, may be connected by way of an inductor to the collector or drain of the NIC functional transistor, with the emitter or source being connected to ground by way of an inductor. The inductors serve to block RF signals. The second biasing circuit applies a second biasing signal across the collector or drain and the emitter or source of the transistor, the second biasing signal controlling a biasing voltage across the drain and the source or the collector and the emitter of the NIC functional transistor.

An advantage of certain embodiments is an enhancement of power efficiency that is adaptive to the power level of the input signal. This advantage may be obtained by way of a biasing network for a cross couple type negative impedance converter which enables the transistor biasing current to be made adaptive to variations of input power level.

A first forward-biased diode and a second forward-biased diode together form a voltage divider to provide a bias voltage to the gate or base of the transistors in the negative impedance converter. A capacitor connected to the first diode couples part of the input RF signal power to RF ground. The first diode rectifies the coupled RF current, causing a DC voltage shift at the gate or base of the associated transistor. As the input power increases, the coupled power and the rectification both increase. As a result, the DC voltage drop across the first forward-biased diode gets smaller and the DC voltage at the gate or base of the transistor is higher, so the DC biasing current at the transistor increases and the total linearity of the circuit is enhanced.

The second forward-biased diode, where provided, helps to provide biasing compensation in the event of temperature variation. If there is no need for temperature compensation, the second forward-biased diode can be omitted or replaced with a resistor.

The two forward-biased diodes can be replaced by two appropriately connected transistors, or by one diode and one transistor.

Viewed from a third aspect, there is provided a negative impedance converter for a matching circuit for matching an impedance of an antenna to an impedance of an RF source or load, the negative impedance converter comprising first and second transistors connected in a cross-over configuration, each transistor having a source or emitter, a drain or collector and a gate or base, wherein the source or emitter of one transistor is configured as an RF input port, the source or emitter of the other transistor is configured as an RF output port, the drain or collector of the first transistor is connected to the gate or base of the second transistor and the drain or collector of the second transistor is connected to the gate or base of the first transistor, and an impedance comprising a capacitance, and inductance and a resistance connected in series is provided between the drain or collector of the first transistor and the drain or collector of the second transistor, and further wherein the negative impedance converter is provided with a passive impedance adjustment network connected between the source or emitter of the first transistor and the source or emitter of the second transistor.

The impedance connected between the respective drains or collectors of the first and second transistors determines the negative impedance that is presented by the negative impedance converter as a whole when an RF signal is input to the source or emitter of the first transistor and output from the source or emitter of the second transistor.

The introduction of a combination of all three of negative resistance, negative inductance and negative capacitance by way of providing a resistor, an inductor and a capacitor between the drain or collector of the first transistor and the drain or collector of the second transistor may help to address the problem of potential instability caused by changes in the effective impedance of the antenna. However, it has surprisingly been found that the introduction of this negative impedance may introduce potential instability arising from resonance due to the negative impedance and parasitic capacitance in the transistors of the NIC. Accordingly, the passive impedance adjustment network, which may be external to the NIC, is provided so as to address this potential instability by compensating for the parasitic capacitance and thereby to seek to prevent or reduce the resonance.

The passive impedance adjustment network is effectively connected in parallel with the negative impedance converter, across the respective sources or emitters of the first and second transistors.

The passive impedance adjustment network may comprise at least one resistor connected in parallel with a capacitor.

In certain embodiments, the impedance adjustment network comprises a first resistor connected in parallel with a first capacitor, followed by a second resistor connected in parallel with a second capacitor. In these embodiments, the passive impedance network is intended to adjust the impedance converted by the negative impedance converter around the in-band frequencies. This adjustment helps to improve the in-band matching performance (total efficiency and return loss) and to avoid excessive negative resistance (which can cause instability).

In other embodiments, the passive impedance adjustment network may comprise just a single capacitor connected in parallel with the negative impedance converter, across the respective sources or emitters of the first and second transistors. This is the simplest form of passive impedance adjustment network. A resistor may be placed in parallel or in series with the capacitor in order to strengthen the adjustment effect. Alternatively or in addition, an inductor and a series-connected resistor can be placed in parallel with the capacitor.

In certain embodiments, the capacitor(s) in the passive impedance network may be a simple fixed capacitor(s), with a capacitance selected to be the same value as the combined parasitic capacitances in the transistors of the NIC. Accordingly, there is no need for expensive varactors or variable capacitors.

The first and second transistors of the negative impedance converter may be biased as required.

### BRIEF DESCRIPTION OF THE DRAWINGS

Embodiments of the invention are further described hereinafter with reference to the accompanying drawings, in which:

FIG. 1 shows an electrically small antenna connected to a 50 ohm signal port;

FIG. 2 shows the antenna of FIG. 1 represented as an equivalent series connected resistor, capacitor and inductor;

FIG. 3 shows the arrangement of FIG. 2 provided with a passive impedance matching network, together with a plot of reactance against angular frequency;

FIG. 4 shows the arrangement of FIG. 2 provided with a non-Foster matching network comprising a negative capacitance, together with a plot of reactance against angular frequency;

FIG. 5 illustrates an antenna circumscribed by a sphere of radius a;

FIG. 6 is a schematic of a conventional Linvill type negative impedance converter (NIC);

FIG. 7 shows a conventional NIC arrangement for matching an antenna to a transceiver;

FIG. 8 is a schematic of a conventional Linvill type negative impedance converter (NIC);

FIG. 9 shows a conventional NIC arrangement for matching an antenna to a transceiver;

FIG. 10 shows an NIC-based matching circuit for an electrically small antenna;

FIG. 11 shows the NIC of FIG. 10 in more detail;

FIG. 12 shows a conventional biasing circuit for one transistor in an NIC;

FIG. 13 shows a first embodiment;

FIG. 14 shows a second embodiment;

FIG. 15 shows a third embodiment;

FIG. 16 shows a plot of gain vs. power for the circuits of FIGS. 12, 13 and 14;

FIG. 17 shows an NIC with an impedance adjustment network in accordance with the third aspect;

FIG. 18 shows an implementation of the NIC of FIG. 17;

FIG. 19 is an alternative schematic showing the NIC of FIG. 15 being used to match an antenna to a feeding port;

FIG. 20 is a plot comparing the input impedance of a conventional NIC with the input impedance of an NIC as shown in FIG. 17; and

FIG. 21 is a plot comparing the matching performance of a conventional NIC with the matching performance of an NIC as shown in FIG. 17;

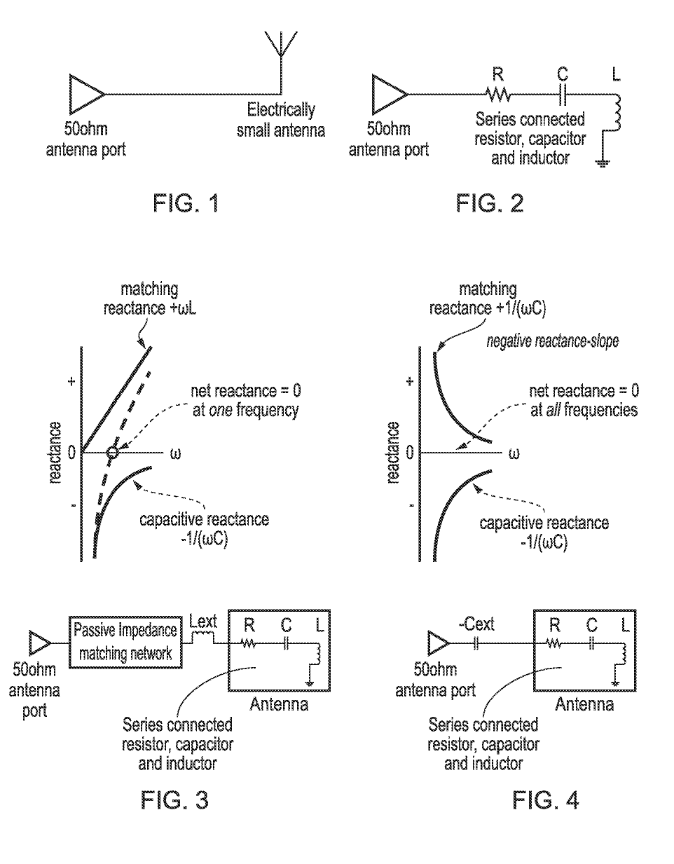

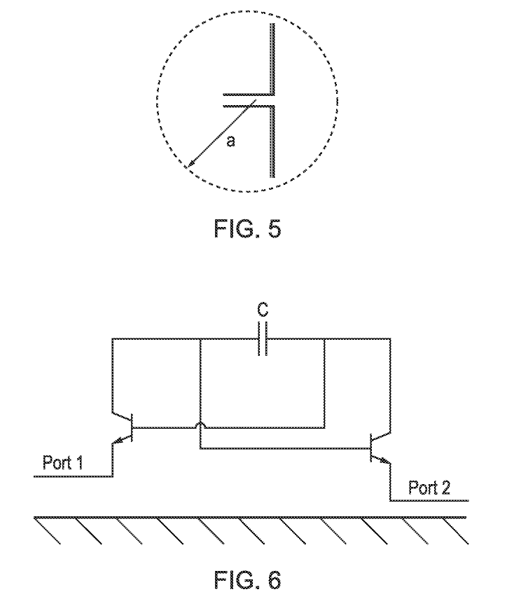

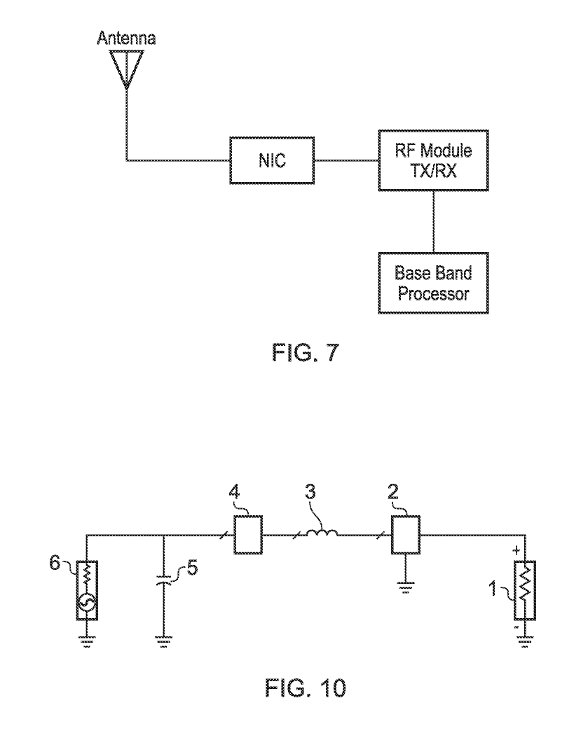

### DETAILED DESCRIPTION

FIG. 10 illustrates an embodiment comprising an NIC-based matching circuit for an electrically small antenna. The circuit comprises an output termination 1, a two-port antenna model 2, a neutralization inductor 3, an NIC block 4, a capacitor 5 for impedance transformation and an RF source 6.

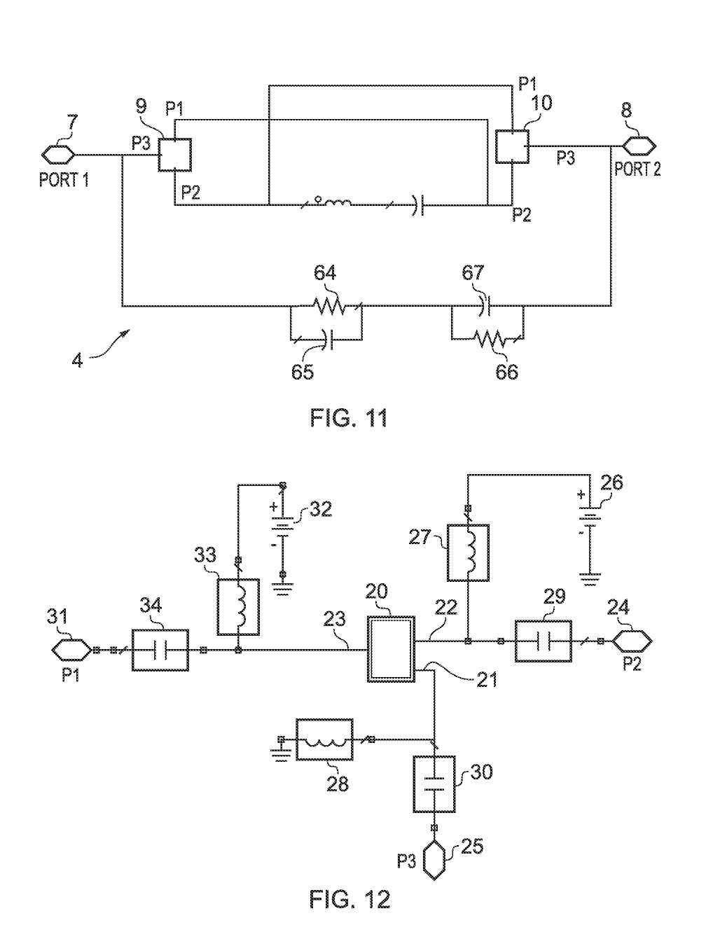

FIG. 11 shows the NIC block 4 in more detail, the NIC including an input port 7 connected to the emitter or source port P3 of a first transistor sub-circuit 9, and an output port 8 connected to the emitter or source port P3 of a second transistor sub-circuit 10. The transistor sub-circuits 9, 10 are connected in a cross-over configuration, with the base or gate port P1 of the first transistor sub-circuit 9 connected to the collector or drain port P2 of the second transistor sub-circuit 10, and the collector or drain port P2 of the first transistor sub-circuit 9 connected to the base or gate port P1 of the second transistor sub-circuit 10. A capacitor 100 and a lossy inductor 101 are connected between the collector or drain ports P2 of the transistor sub-circuits 9, 10, the capacitor 100 and inductor 101 defining the negative impedance that is presented by the NIC block 4 between its input port 7 and output port 8. By applying a negative impedance to the RF signal passing from input port 7 to output port 8, the NIC block 4 can match the RF signal to the antenna.

The NIC block 4 further comprises parallel-connected passive components in the form of resistors 64, 66 and capacitors 65, 67 which are used to adjust the impedance of the NIC block 4, thereby to enhance matching performance, linearity and stability.

Impedance tuning of the NIC block 4 can be controlled by some external device such as a microprocessor (not shown).

FIG. 12 shows one of the transistor sub-circuits 9, 10 of FIG. 11 in more detail, shown here configured with known biasing circuitry so as to illustrate present embodiments more clearly. The sub-circuit comprises a transistor 20 having an emitter or source 21, a collector or drain 22 and a base or gate 23. The base or gate 23 of the transistor 20 is connected to port P1 by way of a DC block 34. A first DC biasing signal is applied to the gate 23 by a DC source 32 and an inductor 33. The emitter or source 21 is connected to port P3 by way of a DC block 30, and the collector or drain 22 is connected to port P2 by way of a DC block 29. A second DC biasing signal is applied between the collector or drain 22 and the emitter or source 21 by way of DC source 26. Inductors 27 and 28 are provided to block RF signals. The DC source 32 controls the bias current and the DC source 26 controls the bias voltage across the collector or drain 22 and the emitter or source 21 of the transistor 20. The DC blocks 29, 30, 34 are provided to isolate the ports P2, P3, P1 from the biasing signals.

To achieve high linearity and simultaneous transmit and receive, the functional transistors in the NIC are preferably biased in a Class-A (linear) bias condition.

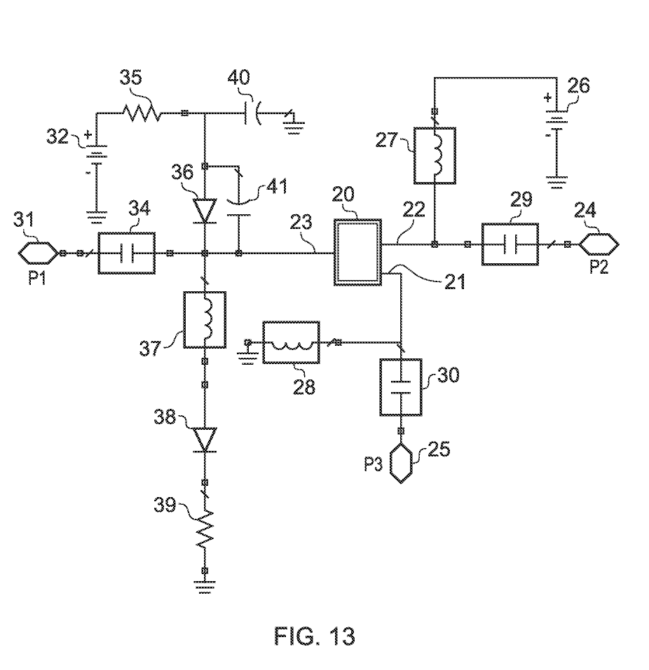

FIG. 13 shows a first embodiment, comprising a transistor sub-circuit 9, 10 based around a transistor 20. The sub-circuit comprises a transistor 20 having an emitter or source 21, a collector or drain 22 and a base or gate 23. The base or gate 23 of the transistor 20 is connected to port P1 by way of a DC block 34. A first DC biasing signal is applied to the gate 23 by a DC source 32. The first biasing signal passes through a first resistor 35, a first diode 36, an inductor 37, a second diode 38 and a second resistor 39 to ground. A first capacitor 40 connects the input to the first diode 36 to ground, and a second capacitor 41 is connected in parallel with the first diode 36. The first and second diodes 36, 38 have the same polarity. Resistors 35 and 39 are configured as a potential divider and can be adjusted so as to vary the first biasing signal as required, together with the diodes 36, 38. The first diode 36 and the capacitors 40, 41 help to promote RF power linearization. The emitter or source 21 is connected to port P3 by way of a DC block 30, and the collector or drain 22 is connected to port P2 by way of a DC block 29. A second DC biasing signal is applied between the drain 22 and the source 21 by way of DC source 26. Inductors 27 and 28 are provided to block RF signals. The DC source 32 controls the bias current and the DC source 26 controls the bias voltage. The DC blocks 29, 30, 34 are provided to isolate the ports P2, P3, P1 from the biasing signals.

In the embodiment of FIG. 13, the first and second diodes 36, 38 only have a DC connection to the base or gate 23 of the transistor 20 rather than to the collector or drain 22 due to the DC block capacitors 29, 34. The two diodes 36, 38 form a voltage divider to provide DC voltage to the base or gate 23. In addition, a coupling capacitor 40 is used to couple the input signal power and to provide voltage rectification with the first diode 36. This applies also to the embodiments of FIGS. 12 and 13.

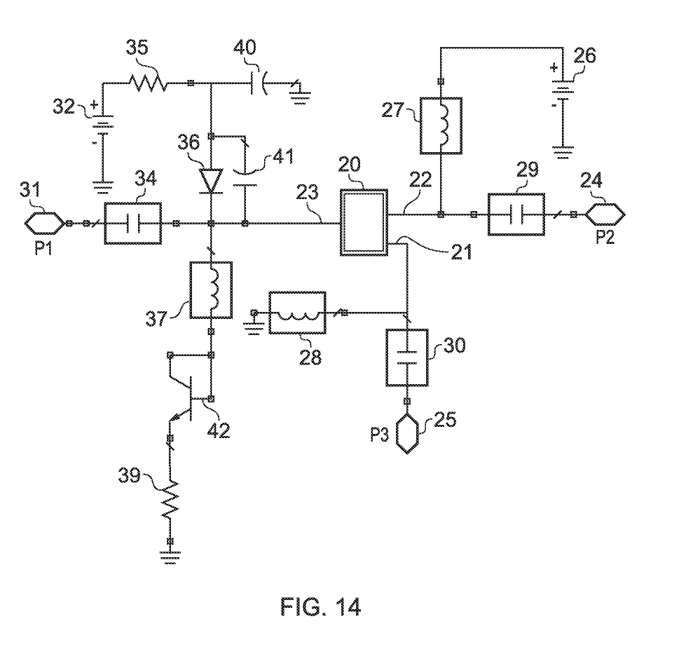

FIG. 14 shows an alternative implementation of the FIG. 13 embodiment, in which the second diode 38 is replaced with a further transistor 42.

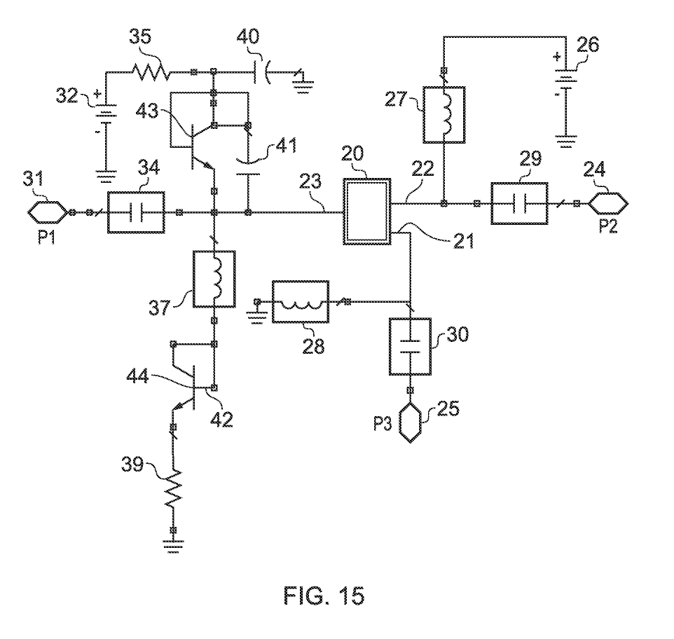

A further alternative implementation of the FIG. 13 embodiment is shown in FIG. 15, where both the first and second diodes 36, 38 are replaced with a third transistor 43 and a further transistor 44.

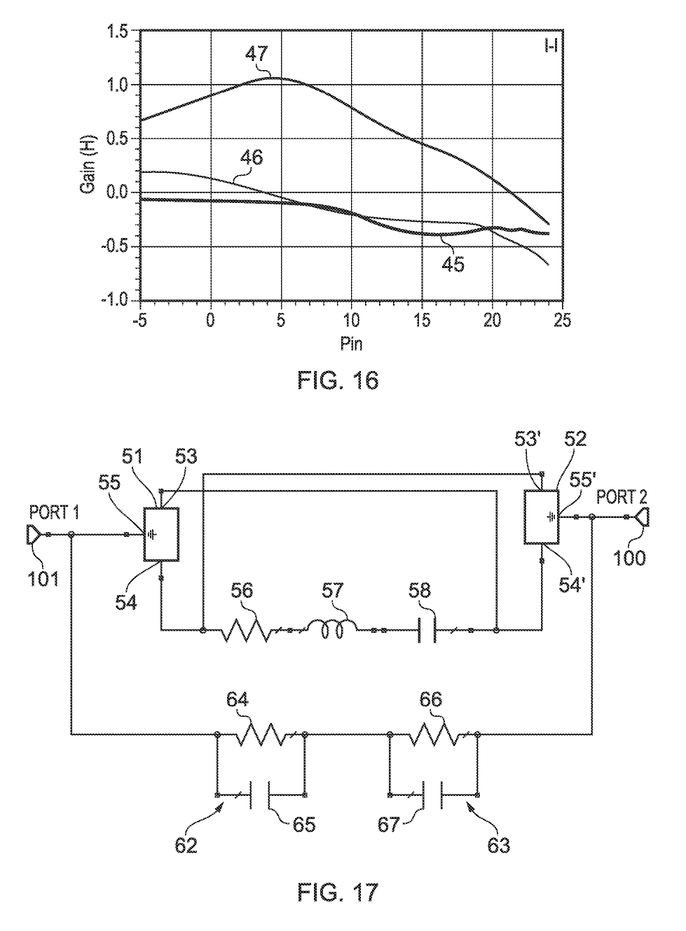

The three biasing circuits shown in FIGS. 12 (prior art), 13 (two diodes) and 14 (one diode, one transistor) were tested with the two main RF transistors in the NIC 4 biased at 40 mA and 2.5V. FIG. 16 shows a plot of gain against power (in) for the different biasing circuits, with the plot for the FIG. 12 circuit identified at 45, the plot for the FIG. 13 embodiment identified at 46, and the plot for the FIG. 14 embodiment identified at 47.

Table 1 below gives the values for IMD3 (in dBc) for the different biasing circuits of FIGS. 12, 13 and 14.

TABLE 1

| | | | | 821 MHz | | | | 851 MHz | | | | 881 MHz | | | |
|---|---|---|---|---|---|---|---|---|---|---|---|---|---|---|---|
| Pin (dBm) | 0 | 5 | 10 | 15 | 20 | 0 | 5 | 10 | 15 | 20 | 0 | 5 | 10 | 15 | 20 |
| FIG. 12 | −50 | −38 | −23 | −18 | −17 | −52 | −39 | −24 | −20 | −18 | −57 | −44 | −27 | −23 | −22 |
| FIG. 13 | −44 | −41 | −42 | −45 | −43 | −38 | −38 | −41 | −45 | −37 | −36 | −37 | −40 | −45 | −37 |
| FIG. 14 | −77 | −55 | −42 | −41 | −40 | −71 | −43 | −36 | −42 | −35 | −60 | −39 | −34 | −36 | −33 |

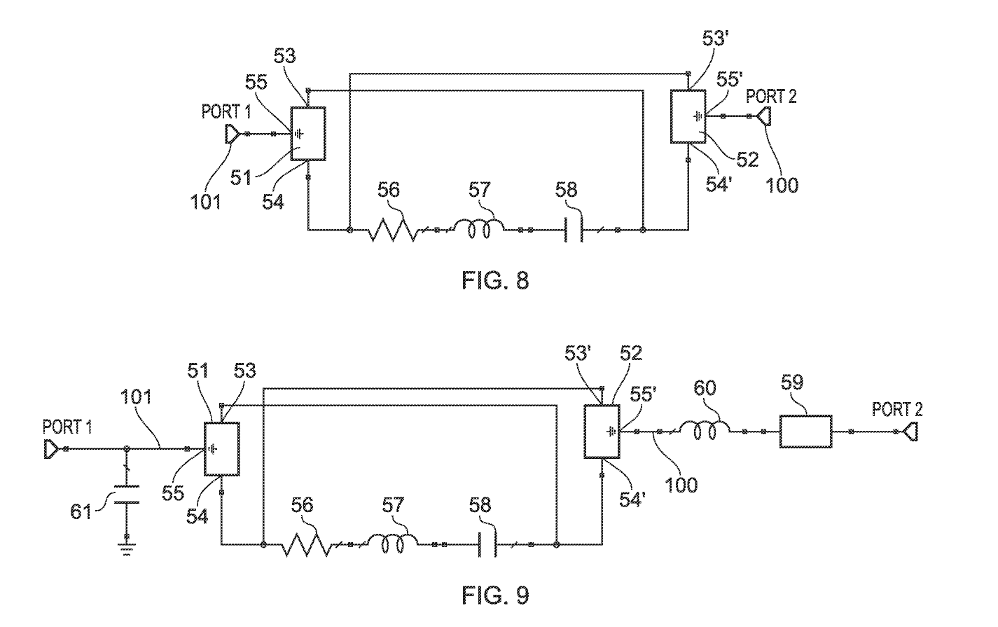

FIG. 17 shows an NIC similar to that of FIG. 8, but provided with an impedance adjustment network in accordance with the third aspect. The NIC comprises first and second biased transistors 51, 52 connected in a crossover configuration. The NIC may comprise field effect transistors, in which case the transistors 51, 52 will have a source 55, 55′, a drain 54, 54′ and a gate 53, 53′. Alternatively, the NIC may comprise bipolar junction transistors, in which case the transistors 51, 52 will have an emitter 55, 55′, a collector 54, 54′ and a base 53, 53′.

The collector or drain 54 of the first transistor 51 is connected to the base or gate 53′ of the second transistor 52, and the collector or drain 54′ of the second transistor 52 is connected to the base or gate 53 of the first transistor 51. A predetermined impedance is provided between the respective collectors or drains 54, 54′ on the one hand, and the respective bases or gates 53, 53′ on the other hand, of the first and second transistors 51, 52. The predetermined impedance determines the negative impedance that the NIC applies to an RF signal passing between the input port 100 and the output port 101. The predetermined impedance is represented by a resistor 56, an inductor 57 and a capacitor 58 connected in series between the respective collectors or drains 54, 54′.

An impedance adjustment network is provided in the form of first and second parallel resistor-capacitor banks 62, 63 connected in series to form a two terminal network. The impedance adjustment network is connected between the sources or emitters 55, 55′ of the first and second transistors 51, 52 as shown. The first resistor-capacitor bank 62 comprises a resistor 64 and a capacitor 65 connected in parallel, and the second resistor-capacitor bank 63 comprises a resistor 66 and a capacitor 67 connected in parallel.

FIG. 18 shows how the NIC with impedance adjustment network of FIG. 17 can be implemented as a non-Foster matching circuit for an electrically small antenna 59. An external inductor 60 is connected between the antenna 59 and the source or emitter 55′ of the second transistor 52. The negative impedance generated by the NIC is used to neutralise the reactance of the external inductor 60 and the antenna 59. An external capacitor 61 is connected to the source or emitter 55 of the first transistor 51 so as to transform the neutralised impedance to 50Ω at the RF output port 101 of the NIC. The first and second parallel resistor-capacitor banks 62, 63 constitute the passive impedance adjustment network.

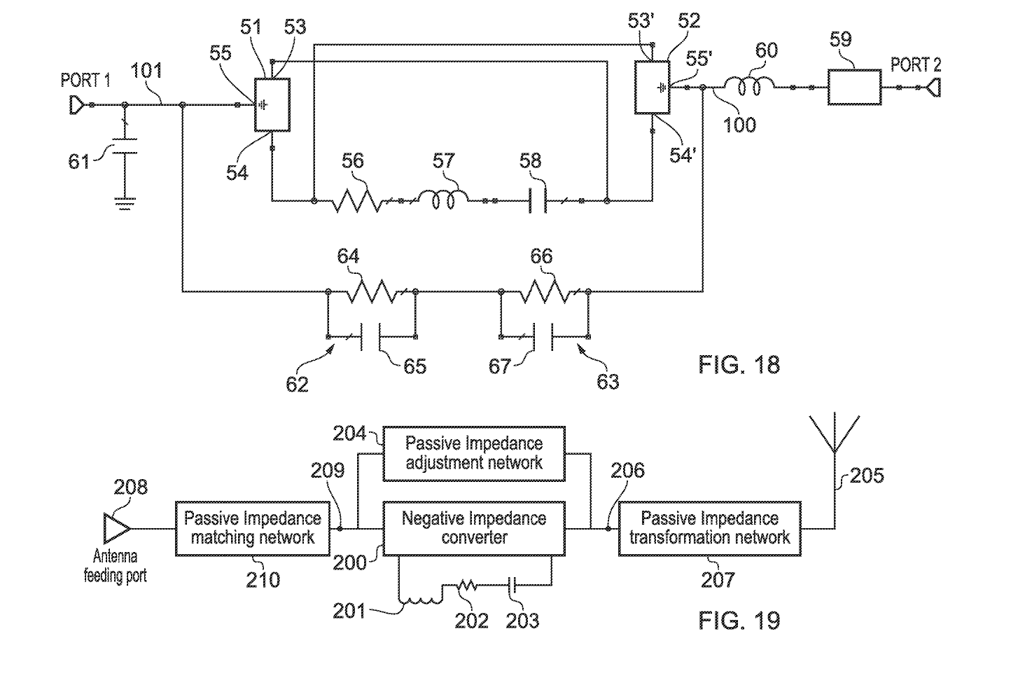

FIG. 19 shows the arrangement of FIG. 18 in more general block form. An NIC 200 includes an impedance represented here by a series inductor 201, capacitor 202 and resistor 203, this impedance determining the negative impedance applied by the NIC 200. A passive impedance adjustment network 204 as described above is connected in parallel with the NIC 200. An electrically small antenna 205 is connected to the RF output 206 of the NIC 200 by way of a passive impedance transformation network 207. An antenna feeding port 208 is connected to the RF input 209 of the NIC 200 by way of another passive impedance transformation network 210.

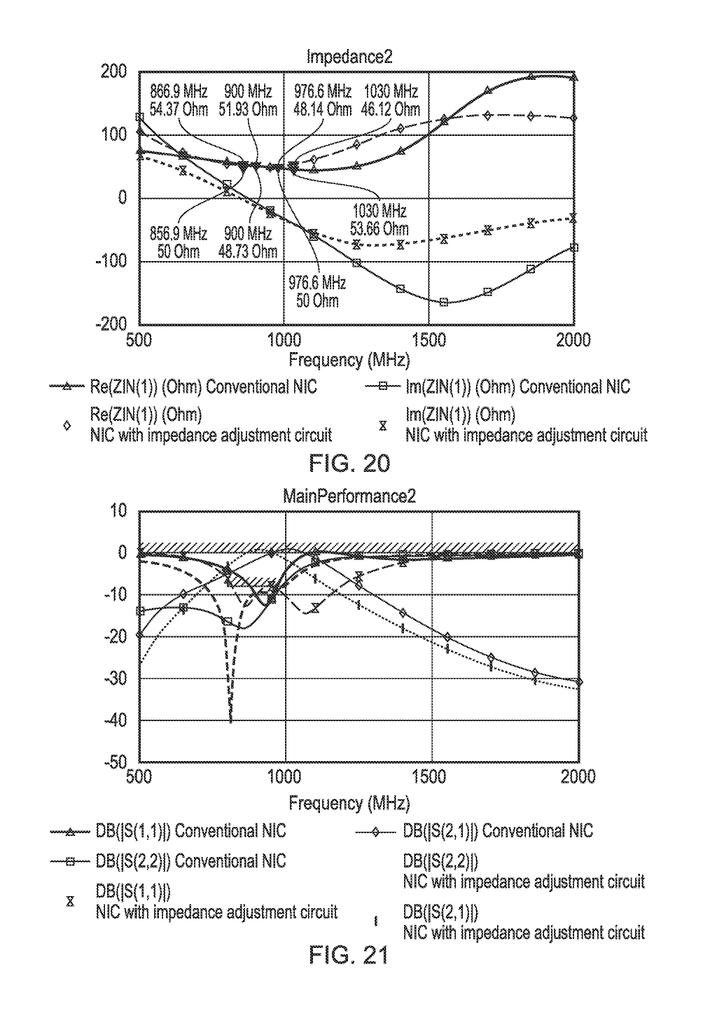

To demonstrate the surprising technical benefits obtained by the impedance adjustment network of present embodiments, reference shall now be made to FIG. 20, which shows the input impedance of the conventional NIC of FIG. 8 compared to the input impedance of the NIC with the impedance adjustment network of FIG. 17 across a range of frequencies. From FIG. 20, it can be seen that in the conventional NIC, the real part of the impedance decreases monotonically from a value of 54.37Ω (significantly higher than 50Ω) at 856.9 MHz to a value of 46.12Ω (significantly lower than 50Ω) at 1030 MHz. This means that the total efficiency is degraded at lower frequencies and that stability is a potential problem. In contrast, when the impedance adjustment network is implemented, the real part of the impedance has a local minimum of 48.73Ω at around 900 MHz, and is 50Ω at both 856.9 MHz and 976.6 MHz. At 1030 MHz, the real part of the impedance is 53.56Ω. It can also be seen that the imaginary part of the impedance has much slower variation when the impedance adjustment network is implemented. As a consequence, the impedance adjustment network improves the matching performance and stability of the whole circuit.

FIG. 21 shows how the matching performance of the circuit of FIG. 9 is improved by provision of the impedance adjustment network as shown in FIG. 18. In the conventional NIC circuit of FIG. 9, the S-parameter curves have uneven shapes, and at some frequency points, both high total efficiency and high return loss occur simultaneously. By providing an impedance adjustment network as hereinbefore described, the shapes of the S-parameter curves assume more well-behaved shapes, and high total efficiency corresponds appropriately to a low return loss.

The resistor/capacitor banks 62, 63 may be replaced by a single capacitor, or several capacitors. What is important is that the passive impedance adjustment network 204 is configured to compensate for parasitic capacitance in the transistors 51, 52. In some embodiments, this may be achieved by configuring the passive impedance adjustment network to have a capacitance substantially equal to the parasitic capacitance in the transistors 51, 52.

Throughout the description and claims of this specification, the words “comprise” and “contain” and variations of them mean “including but not limited to”, and they are not intended to (and do not) exclude other moieties, additives, components, integers or steps. Throughout the description and claims of this specification, the singular encompasses the plural unless the context otherwise requires. In particular, where the indefinite article is used, the specification is to be understood as contemplating plurality as well as singularity, unless the context requires otherwise.

Features, integers, characteristics, compounds, chemical moieties or groups described in conjunction with a particular aspect, embodiment or example of the invention are to be understood to be applicable to any other aspect, embodiment or example described herein unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The invention is not restricted to the details of any foregoing embodiments. The invention extends to any novel one, or any novel combination, of the features disclosed in this specification (including any accompanying claims, abstract and drawings), or to any novel one, or any novel combination, of the steps of any method or process so disclosed.

The reader's attention is directed to all papers and documents which are filed concurrently with or previous to this specification in connection with this application and which are open to public inspection with this specification, and the contents of all such papers and documents are incorporated herein by reference.

1. A negative impedance converter for a matching circuit for matching an impedance of an antenna to an impedance of an RF source or load, the negative impedance converter comprising first and second transistors connected in a cross-over configuration, each transistor having a source or emitter, a drain or collector and a gate or base, and each transistor further having a first biasing circuit connected only to its gate or base and not to the drain or collector of the other transistor, wherein the first biasing circuit comprises a first DC biasing signal source and a first diode connected between the first DC biasing signal source and the gate or base.

2. A negative impedance converter for a matching circuit for matching an impedance of an antenna to an impedance of an RF source or load, the negative impedance converter comprising first and second transistors connected in a cross-over configuration, each transistor having a source or emitter, a drain or collector and a gate or base, and each transistor further having a first biasing circuit connected only to its gate or base and not to the drain or collector of the other transistor, wherein the first biasing circuit comprises a first DC biasing signal source and a third transistor connected between the first DC biasing signal source and the gate or base.

3. The negative impedance converter as claimed in claim 1, further comprising a second diode connected in series with the first diode or the third transistor.

4. The negative impedance converter as claimed in claim 1, further comprising a further transistor connected in series with the first diode or the third transistor.

5. The negative impedance converter as claimed in claim 1, wherein the gate or base of each of the first and second transistors is provided with a conductive gate or base connection to allow an RF signal to be connected to the gate or base.

6. The negative impedance converter as claimed in claim 5, wherein the gate or base connection of each of the first and second transistors is connected to the respective first biasing circuit between the respective first and second diodes, third transistor and further transistor, or first diode and further transistor.

7. The negative impedance converter as claimed in claim 1, wherein the first biasing circuit of each of the first and second transistors further comprises one or more resistors, capacitors and/or inductors so as to allow the first DC biasing signal to be conditioned as required.

8. The negative impedance converter as claimed in claim 1, wherein for each of the first and second transistors, the first and second diodes or third transistor and further transistor or first diode and further transistor are connected in series with each other with the same polarity, and are connected between the first DC biasing signal source and ground.

9. The negative impedance converter as claimed in claim 8, wherein for each of the first and second transistors, resistors are provided in the first biasing circuit to act as a potential divider, thereby allowing the first biasing circuit to apply the required first DC biasing signal to the base or gate.

10. The negative impedance converter as claimed in claim 1, wherein for each of the first and second transistors, a first capacitor is connected in parallel with the first diode or third transistor.

11. The negative impedance converter as claimed in claim 10, wherein for each of the first and second transistors, an additional capacitor is connected between an input of the first diode or third transistor and ground, so as to enable a DC operation current to increase adaptively with an increase in an input signal power level.

12. The negative impedance converter as claimed claim 1, wherein for each of the first and second transistors, an inductor is connected between the first and second diodes, or between the third transistor and the further transistor or between the first diode and the further transistor.

13. The negative impedance converter as claimed in claim 1, wherein for each of the first and second transistors, there is provided a second biasing circuit connected across the collector or drain and the emitter or source of the transistor.

14. The negative impedance converter as claimed in claim 13, wherein the second biasing circuit of each of the first and second transistors further comprises a second DC biasing signal source.

15. The negative impedance converter as claimed in claim 13, wherein for each of the first and second transistors, the second biasing circuit is connected by way of an inductor to the collector or drain of the transistor, and wherein the emitter or source is connected to ground by way of a further inductor.

16. The negative impedance converter as claimed in claim 1, further comprising an RF input port connected to the emitter or source of the first transistor, and an RF output port connected to the emitter or source of the second transistor.

17. The negative impedance converter as claimed in claim 16, further comprising at least one capacitor connected in parallel between the RF input port and RF output port.

18. The negative impedance converter as claimed in claim 17, further comprising at least one resistor connected in parallel with the at least one capacitor.

19. The negative impedance converter as claimed in claim 1, wherein the collector or drain of the first transistor is connected to the base or gate of the second transistor, and the collector or drain of the second transistor is connected to the base or gate of the first transistor.

20. The negative impedance converter as claimed in claim 19, wherein a predetermined impedance is provided between the respective collectors or drains on the one hand, and the respective bases or gates on the other hand, of the first and second transistors.

21. The negative impedance converter as claimed in claim 20, wherein the predetermined impedance determines the negative impedance that the NIC applies to an RF signal passing between the input port and the output port.

22. The negative impedance converter as claimed in claim 21, wherein the predetermined impedance is adjustable.

23. The negative impedance converter as claimed in claim 22, wherein the predetermined impedance comprises a variable capacitor and/or a variable inductor.

24. The negative impedance converter as claimed in claim 22, wherein the predetermined impedance is configured to be adjustable by way of a control input from a digital controller.

25. A negative impedance converter for a matching circuit for matching an impedance of an antenna to an impedance of an RF source or load, the negative impedance converter comprising first and second transistors connected in a cross-over configuration, each transistor having a source or emitter, a drain or collector and a gate or base, wherein the source or emitter of one transistor is configured as an RF input port, the source or emitter of the other transistor is configured as an RF output port, the drain or collector of the first transistor is connected to the gate or base of the second transistor and the drain or collector of the second transistor is connected to the gate or base of the first transistor, and an impedance comprising a capacitance, and inductance and a resistance connected in series is provided between the drain or collector of the first transistor and the drain or collector of the second transistor, and further wherein the negative impedance converter is provided with a passive impedance adjustment network connected between the source or emitter of the first transistor and the source or emitter of the second transistor.

26. The negative impedance converter as claimed in claim 25, wherein the passive impedance adjustment network comprises at least one resistor connected in parallel with a capacitor.

27. The negative impedance converter as claimed claim 25, wherein the passive impedance adjustment network comprises a first parallel resistor-capacitor bank connected in series with a second parallel resistor-capacitor bank.

28. The negative impedance converter as claimed in claim 25, wherein the passive impedance adjustment network comprises a capacitor.

29. The negative impedance converter as claimed in claim 28, wherein the passive impedance adjustment network further comprises a resistor connected in series with the capacitor.

30. A negative impedance converter as claimed in claim 28, wherein the passive impedance adjustment network further comprises a resistor connected in parallel with the capacitor.

31. The negative impedance converter as claimed in claim 28, wherein the passive impedance adjustment network further comprises a resistor and an inductor connected in parallel with the capacitor.

32. The negative impedance converter as claimed in claim 25, wherein the capacitor or capacitors in the passive impedance adjustment network provide a total capacitance selected so as to compensate for a total parasitic capacitance introduced by the first and second transistors.

33. The negative impedance converter as claimed in claim 25, wherein the capacitor or capacitors in the passive impedance adjustment network is or are of fixed value capacitance.

35. (canceled)

36. (canceled)
